(19) United States
(12) Patent Application Publication
(10) Pub. No.: US 2022/0377921 A1
(43) Pub. Date: Nov. 24, 2022

(54) COVER WINDOW, METHOD OF PROVIDING COVER WINDOW, AND DISPLAY DEVICE INCLUDING COVER WINDOW

(71) Applicant: Samsung Display Co., LTD., Yongin-si (KR)

(72) Inventors: Joo Hyeon Lee, Suwon-si (KR); Ji Eun Nam, Seoul (KR); Heon Jung Shin, Hwaseong-si (KR)

(21) Appl. No.: 17/515,744

(22) Filed: Nov. 1, 2021

(30) Foreign Application Priority Data
May 24, 2021 (KR) 10-2021-0066230

(51) Int. Cl. H05K 5/03; B32B 3/30; B32B 7/12; B32B 27/36; B32B 27/08; B32B 27/34; B32B 27/28

(52) U.S. Cl. CPC H05K 5/03; B32B 3/30; B32B 7/12; B32B 27/36; B32B 27/08; B32B 27/34; B32B 27/281; H05K 5/0017

(57) ABSTRACT

A cover window includes a first film, an adhesive layer below the first film, and a second film below the adhesive layer. The second film includes a base substrate and a pattern layer which is on the base substrate and includes a plurality of protrusions. The pattern layer includes a plurality of protrusions that become narrower in a direction towards the first film. A modulus of the base substrate is about 500 megapascals (MPa) to about 1.5 gigapascals (GPa) when a modulus of the pattern layer is about 5 MPa to about 20 MPa, or the modulus of the base substrate is about 3.5 GPa or more when the modulus of the pattern layer is about 30 MPa to about 50 MPa.

This application claims priority to Korean Patent Application No. 10-2021-0066230 filed on May 24, 2021, and all the benefits accruing therefrom under 35 U.S.C. § 119, the entire contents of which are incorporated herein by reference.

### BACKGROUND

### (a) Field

The present disclosure relates to a cover window, a method for manufacturing (or providing) the cover window, and a display device including the cover window.

### (b) Description of the Related Art

A display device such as an organic light emitting diode (OLED) display, a liquid crystal display (LCD), and the like includes a display panel that is manufactured by forming a plurality of layers and elements on a substrate. A flexible display panel and a flexible display device including the same have been developed.

The flexible display device may be classified into a bendable display device, a foldable display device, a rollable display device, a stretchable display device, and the like according to a use or form thereof. Among these, the foldable display devices can be folded and unfolded like a book.

The above information disclosed in this Background section is only for enhancement of understanding of the background of the invention, and therefore it may contain information that does not form the prior art that is already known in this country to a person of ordinary skill in the art.

### SUMMARY

A cover window is disposed on a top of a display panel. When an external impact is applied to the cover window, such as when an external object such as a pen falls on the cover window, the cover window may be destroyed or the impact from the external impact may propagate to the display panel, causing damage to the display panel. In particular, when sharpness of the tip of the pen increases for touch precision, the impact amount increases, and thus the risk of cracks in the cover window or datnage to the display panel may be increased.

Embodiments of the present disclosure provide a thin cover window of a display device while improving the impact characteristic of the cover window used in the display device.

An embodiment of a cover window includes a first film, an adhesive layer below the first film, and a second film below the adhesive layer. The second film includes a base substrate and a pattern layer which is on the base substrate and includes a plurality of protrusions. The pattern layer includes a plurality of protrusions that become narrower in a direction towards the first film, a modulus of the base substrate is about 500 megapascals (MPa) to about 1.5 gigapascals (GPa) when a modulus of the pattern layer is about 5 MPa to about 20 MPa, or the modulus of the base substrate is about 3.5 GPa or more when the modulus of the pattern layer is about 30 MPa to about 50 MPa.

The first film may include a protection film defining a top surface of the cover window.

The pattern layer may include at least one of an actyl-based, urethane-based, and silicone-based polymer resin.

The base substrate may include at least one of an amide-based, ester-based, ether-based, and carbonate-based polymer material.

The base substrate may include at least one of a terephthalate-based, imide-based, and aramid-based polymer material.

The protrusion may include a high point farthest from the base substrate and a low point closest to the base substrate, and the low point may contact a top surface of the base substrate.

The protrusion may include a high point farthest from the base substrate and a low point closest to the base substrate, and the low point may be distanced from a top surface of the base substrate rather than contacting the top surface of the base substrate.

The protrusion may include a high point farthest from the base substrate and a low point closest to the base substrate, and the high point is a flat surface at a boundary with the adhesive layer.

The cover window may further include a filling layer in a space defined between the plurality of protrusions, where the filling layer may include a same material as the adhesive laver.

The protrusion may be in a shape of a prism or microlens.

An embodiment of a display device includes a display panel and a cover window which is on the display panel. The cover window includes a first film, an adhesive layer below the first film, and a second film below the adhesive layer. The second film includes a base substrate, and a pattern layer which is on the base substrate and includes a plurality of protrusions. The pattern layer includes a plurality of protrusions that become narrower in a direction away from the display panel.

The first film may include a protection film defining a top surface of the cover window.

The protrusion may include a high point farthest from the base substrate and a low point closest to the base substrate, and the low point may contact a top surface of the base substrate.

The protrusion may include a high point farthest from the base substrate and a low point closest to the base substrate, and the low point may be distanced from a top surface of the base substrate rather than contacting the top surface of the base substrate.

The protrusion may include a high point farthest from the base substrate and a low point closest to the base substrate, and the high point may define a fiat surface at a boundary with the adhesive layer.

The display device may further include a filling layer in a space between the plurality of protrusions, where the filling layer may include a same material as the adhesive layer.

A modulus of the base substrate may be about 500 MPa to about 1.5 GPa when a modulus of the pattern layer may be about 5 MPa to about 20 MPa.

The base substrate may include at least one of an amide-based, ester-based, ether-based, and carbonate-based polymer material, and the pattern layer may include at least one of acryl-based, urethane-based, and silicone-based polymer resin.

The base substrate may include at least one of a terephthalate-based, imide-based, and aramid-based polymer material, and the pattern layer may include at least one of an acryl-based, urethane-based, and silicone-based polymer resin.

A method of providing a cover window includes providing a coating layer by providing a polymer resin to a base substrate of the cover window, the base substrate having a modulus, providing a pattern layer of the cover window including a plurality of protrusions arranged along the base substrate, by patterning the coating layer, the pattern layer including each protrusion among the plurality of protrusions having a modulus and a width, and the widths of the protrusions decreasing in a direction away from the base substrate, providing an adhesive layer facing the base substrate with the plurality of protrusions of the pattern layer therebetween and providing a protection film of the cover window which faces the plurality of protrusions of the pattern layer with the adhesive layer therebetween. Within the cover window the modulus of the base substrate is about 500 MPa to about 1.5 GPa when the modulus of the pattern layer is about 5 MPa to about 20 MPa, or the modulus of the base substrate is about 3.5 GPa or more when modulus of the pattern layer is about 30 MPa to about 50 MPa.

According to one or more embodiment, a small thickness of a cover window of a display device may be maintained while improving the impact characteristic of the cover window used in the display device.

### BRIEF DESCRIPTION OF THE DRAWINGS

The above and other advantages and features of this disclosure will become more apparent by describing in further detail embodiments thereof with reference to the accompanying drawings, in which:

FIG. 1 and FIG. 2 are side views of embodiments of a display device which is folded,

FIG. 3 is a schematic perspective view of an embodiment of the display device which is unfolded,

FIG. 4 is a schematic cross-sectional view of an embodiment of the display device including a cover window,

FIG. 5 and FIG. 6 are cross-sectional views of embodiments of a second film of the cover window,

FIG. 7 is a table showing impact absorption rates relative to a modulus of a second film of the cover windows, according to comparative examples and embodiments,

FIG. 8 is a graph showing impact relative to a pen drop height in a pen drop experiment on a cover window including a second film according to the comparative example and the embodiment,

FIG. 9 is a photo of cracks in the cover window relative to a pen drop height, according to the comparative example,

FIG. 10 is a photo of the cover window without cracks relative to a pen drop height, according to the embodiment,

FIG. 11 and FIG. 12 are cross-sectional views of embodiments of a second film and an adhesive layer,

FIG. 13 and FIG. 14 are cross-sectional views of embodiments of a second films,

FIG. 15 and FIG. 16 are cross-sectional views of embodiments of a second film and an adhesive layer.

### DETAILED DESCRIPTION

The invention will be described more fully hereinafter with reference to the accompanying drawings, in which embodiments of the invention are shown. As those skilled in the art would realize, the described embodiments may be modified in various different ways.

The drawings and description are to be regarded as illustrative in nature and not restrictive. Like reference numerals designate like elements throughout the specification. As used herein, a reference number may indicate a singular element or a plurality of the element. For example, a reference number labeling a singular form of an element within the drawing figures may be used to reference a plurality of the singular element within the text of specifi cation

In addition, since the size and thickness of each configuration shown in the drawings are arbitrarily indicated for better understanding and ease of description, the invention is not necessarily limited to the drawings. In the drawings, the thickness of layers, films, panels, regions, etc., are exaggerated for clarity. In addition, in the drawings, the thickness of some layers and regions is exaggerated for better understanding and ease of description.

It will be understood that when an element such as a layer, film, region, or substrate is referred to as being related to another element such as being “on” another element, it can be directly on the other element or intervening elements may also be present. In contrast, when an element is referred to as being related to another element such as being “directly on” another element, there are no intervening elements present. Further, throughout the specification, the word “on” a target element will be understood to mean positioned above or below the target element, and will not necessarily be understood to mean positioned “at an upper side” based on an opposite to gravity direction.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or,” As used herein, the term “and/or” includes any and all combinations of one or more of the associated listed items. In addition, unless explicitly described to the contrary, the word “comprise”, and variations such as “comprises” or “comprising”, will be understood to imply the inclusion of stated elements but not the exclusion of any other elements.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ± 30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Further, throughout the specification, the phrase “on a plane” means viewing a target portion from the top, and the phrase “on a cross-section” means viewing a cross-section formed by vertically cutting a target portion from the side.

In addition, when “connected to” in the entire specification, this does not only mean that two or more constituent elements are directly connected, but also means that two or more constituent elements are indirectly connected, physically connected, and electrically connected through other constituent elements, or being referred to by different names depending on the position or function, while being integral.

Hereinafter, an embodiment of a cover window 100 and a display device which includes the cover window 100 will be described with the accompanying drawings.

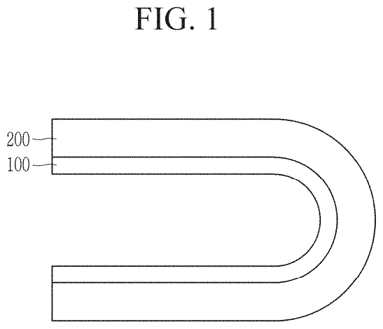

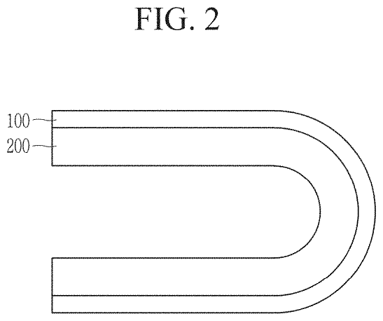

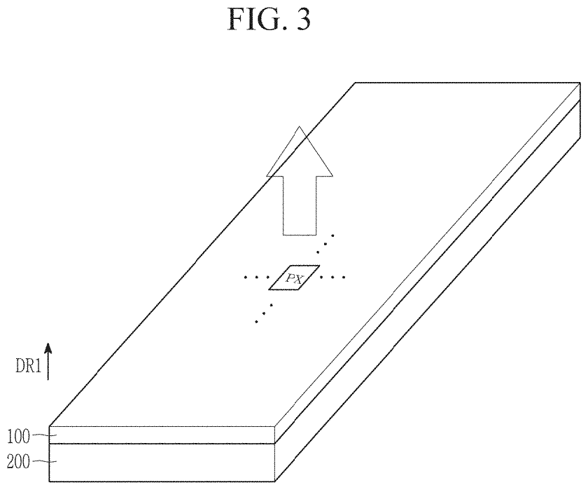

FIG. 1 and FIG. 2 are side views of an embodiment of a display device which is folded, and FIG. 3 is a schematic perspective view of an embodiment of the display device which is unfolded (or flat).

Referring to FIG. 1 and FIG. 2, a display device may be a foldable display device. As shown in FIG. 1, a display device may include a display panel 200 and a cover window 100 which is on a side of the display panel 200. The cover window 100 may be on the display surface of the display panel 200 and/or may define a display surface of the display device, without being limited thereto.

Referring to FIG. 1, the display device may be folded such that portions of the cover window 100 face each other (e.g., in-folded). That is, portions of a display surface may face each other and may not be exposed (e.g., may not face outside of the display device) when the display device is folded, and may be exposed (e.g., may face outside of the display device) when the display device is unfolded.

Referring to FIG. 2, a display device may be folded such that portions of a display panel 200 may face each other (e.g., out-folded). That is, a display surface may be exposed to the outside when the display device is folded, and the display surface may be exposed even when the display device is unfolded.

Referring to FIG. 3, the display panel 200 may include a plurality of pixels PX that can display an image, emit light, etc. The display panel 200 may be a light emitting display panel of which a pixel PX among the plurality of pixels PX includes a light emitting element or a liquid crystal display panel of which a pixel PX includes a liquid crystal capacitor.

Among surfaces of the display panel 200, a surface on which the cover window 100 is disposed may be a display surface at which the image is displayed. The arrow direction shown in FIG. 3, that is a first direction DR1, is an image display direction. Hereafter, when describing the stacked structure of the cover window 100, “up” means the first direction DR1.

The display device and various components and layers thereof may be disposed in a plane defined by a second direction and a third direction crossing each other and crossing the first direction DR1. A thickness direction of the display device and various components and layers thereof may be taken along the first direction DR1.

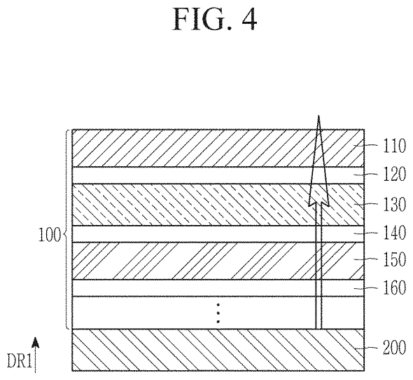

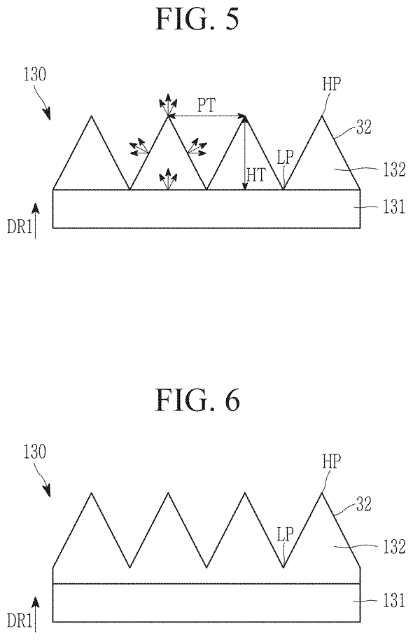

FIG. 4 is a schematic cross-sectional view of an embodiment of the display device including the cover window 100, and FIG. 5 and FIG. 6 are cross-sectional views of embodiments of a second film 130 within the cover window 100.

Referring to FIG. 4, the cover window 100 includes a plurality of films stacked in the first direction DR1, and at least one adhesive layer.

The cover window 100 including the plurality of films and the at least one adhesive layer may have optical clearance (e.g., may be light transmissive, optically clear, etc.).

The plurality of films may include a first film 110 which is a protective film disposed at the topmost of the display device, a second film 130 which is a pattern film disposed below the first film 110 for improving an impact resistance characteristic, and a third film 150 disposed below the second film 130. The first film 110, the second film 130 and the third film 150 may be in order toward the display panel 200.

A first adhesive layer 120 disposed between the first film 110 and the second film 130, a second adhesive layer 140 disposed between the second film 130 and the third film 150, and a third adhesive layer 160 disposed below the third film 150, respectively adhere two neighboring films or layers to each other.

The adhesive layers 120, 140, and 160 may include a pressure sensitive adhesive (PAS). The adhesive layers 120, 140, and 160 may include, for example, a polymer resin such as an acryl-based material, a silicon-based material, rubber, polyurethane, vinyl acetate, an epoxy resin, and styrene-butadiene-styrene (SBS). The second adhesive layer 140 may include an optically clear resin (OCA).

The first film 110 may include at least one of polyethylene terephthalate (PET), poly(butylene terephthalate) (PBT), polycarbonate (PC), polyethylene naphthalate (PEN), polystyrene (PS), poly methylinethacrylate (PMMA), polyvinylchloride (PVC), polyethersulfone (PES), polypropylene (PP), polyamide (PA), modified polyphenylene ether (m-PPO), polyoxymethylene (POM), polysulfone (PSU), polyphenylene sulfide (PPS), polyimide (PI), polyethyleneimine (PEI), polyether ether ketone (PEEK), polyamide imide (PAI), polyarylate (PAR), thermoplastic polyurethane (TPU), and the like.

Like the first film 110, the third film 150 or another one of the first film 110 disposed below the third film 150 may include at least one of various resins. That is, a stacked structure may include each of the first film 110, the second film 130 and the third film 150, and the cover window 100 may include a plurality of the stacked structures, without being limited thereto.

In an embodiment of the cover window 100, the third film 150 and additional films which are below the third film 150 may be omitted.

The second film 130 is a film for impact resistance improvement.

Referring to FIG. 5 and FIG. 6, the second film 130 includes a base substrate 131 and a pattern layer 132 which is disposed on the base substrate 131. Referring to FIG. 5, together with FIG. 4, the pattern layer 132 is disposed between the base substrate 131 and the first film 110, and the base substrate 131 is disposed between the display panel 200 and the pattern layer 132.

According to the physical shape of the base substrate 131 and the pattern layer 132, the base substrate 131 has a substantially flat top surface, and the pattern layer 132 may have a plurality of protrusions 32 (also called protruding portions) that become narrower in the first direction DR1, which is the direction away from the display panel 200.

The protrusion 32 may have various shapes such as, for example, a prism shape and a microlens shape, A width of the protrusion 32 may be taken in a direction along the base substrate 131. A width of the protrusion 32 may decrease in a direction away from the display panel 200.

The protrusion 32 may include a high point HP farthest from the base substrate 131 and a low point LP closest to the base substrate 131. When the protrusion 32 is in the form of a prism, the high point HP may be in the form of a vertex.

As shown in FIG. 5, the low point LP contact the top surface of the base substrate 131 which is closest to the first film 110, such as to be coplanar with the top surface of the base substrate 131. As shown in FIG. 6, the low point LP may be disposed spaced apart from the top surface of the base substrate 131 along the first direction DR1. In case of the embodiment shown in FIG. 5, the pattern layer 132 may have a thickness of substantially zero at the low point LP, and in case of the embodiment of FIG. 6, the pattern layer 132 may have a thickness that is substantially larger than zero at the low point LP.

Referring to FIG. 5, when an impact is transmitted from the top (e.g., in a direction opposite to the first direction DR1), most of the impact is distributed in the upper, upper left, or upper right direction (in a cross-section view) as marked by the multiple arrows from a surface of the protrusion 32 of the pattern layer 132, protruded upward. An impact absorbed into the protrusion 32 can also be reflected at an interface between the protrusion 32 and the base substrate 131. Therefore, it is possible to reduce or effectively prevent the impact from being transmitted to a remainder of the cover window 100 and the display panel 200 which is disposed below the cover window 100.

In addition, the impact transmitted from the top is delayed within the second film 130 including the base substrate 131 and the pattern layer 132 having different materials from each other, and thus the impact can be mitigated from being transmitted to other places.

A pitch PT and a height Hf of the protrusion 32 of the pattern layer 132 may be properly set to reduce or effectively prevent damage to the second film 130 due to a stress applied therein and reduce or effectively prevent deterioration of flexural performance when the display device is being folded to define a curvature radius thereof. In an embodiment, for example, when a curvature radius of the display device is about 1 millimeter when the display device is folded, the pitch PT of a plurality of protrusions 32 may be about 20 micrometers to about 50 micrometers, and the height HT of the protrusions 32 may be about 10 micrometers to about 25 micrometers. The height HT may be taken along the first direction DR1, from the high point HP to a reference plane such as the top surface of the base substrate 131.

The thickness of the base substrate 131 (e.g., along the first direction DR1) may be, for example, about 20 micrometers to about 60 micrometers, but is not limited thereto.

As physical properties of the base substrate 131 and the pattern layer 132, the physical properties of the base substrate 131 and the pattern layer 132, particularly the modulus, improve the impact characteristic that absorbs and disperses impact from the outside.

Specifically, the modulus of the base substrate 131 may be about 500 megapascals (MPa) to about 1.5 gigapascals (GPa), and, in this case, the modulus of the pattern layer 132 may be about 5 MPa to about 20 MPa.

When the modulus of the base substrate 131 is about 3.5 GPa or more, the modulus of the pattern layer 132 may be about 30 MPa to about 50 MPa.

In order to improve the impact resistance characteristic and reduce or effectively prevent damage to the second film 130, when the modulus of the base substrate 131 increases, the modulus of the pattern layer 132 may also increase.

The modulus of the pattern layer 132 may be less than 100 MPa. When the modulus of the pattern layer 132 is 100 MPa or more, the impact may propagate toward the base substrate 131 and the display panel 200 regardless of the modulus of the base substrate 131.

The base substrate 131 and the pattern layer 132 include different materials for the above-mentioned modulus characteristic, and may each include a variety of materials.

In an embodiment, for example, the base substrate 131 having a modulus between about 500 MPa to about 1.5 GPa may include at least one of an amide-based, ester-based, ether-based, and carbonate-based polymer material. That is, the base substrate 131 may include a polymer material including amide, ester, ether or carbon. In an embodiment, for example, the base substrate 131 having a modulus of about 3.5 GPa or more may include at least one of a terephthalate-based, imide-based, and aramid-based polymer material. That is, the base substrate 131 may include a polymer material including terephthalate, imide, or aramid.

The pattern layer 132 may include, for example, at least one of an acryl-based, urethane-based, and silicone-based polymer resin. That is, the pattern layer 132 may include a polymer resin including acryl, urethane or silicone.

A difference in refractive index between the base substrate 131 and the pattern layer 132 may be less than 0.04. In an embodiment, for example, the refractive index of the base substrate 131 may be about 1.49, and the refractive index of the pattern layer 132 may be about 1.495, but is not limited thereto. By reducing the refractive index difference between the base substrate 131 and the pattern layer 132, it is possible to reduce or effectively prevent visual recognition of the protrusion 32 of the pattern layer 132 from outside the cover window 100 and/or the display device.

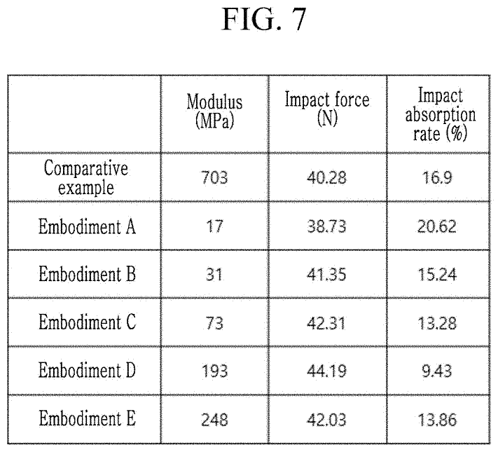

The impact resistance characteristic of embodiments of the cover window 100 that includes the second film 130 will be described with reference to FIG. 7 to FIG. 10.

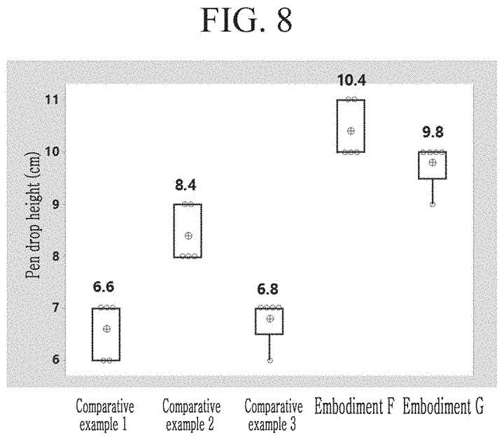

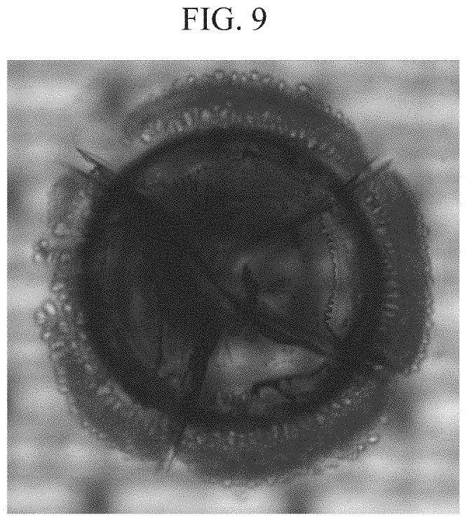

FIG. 7 is a table that shows impact absorption rates of modulus of second films within and of the cover windows according to comparative examples and embodiments, FIG. 8 is a graph that shows impact resistance of a pen drop height (in centimeters, cm) when a pen drop experiment is performed on a cover window 100 including the second film 130 according to the comparative example and the embodiment, FIG. 9 is a photo of cracks that occurred on the cover window 100 when the pen was dropped from a height on the cover window 100 according to the comparative example, and FIG. 10 is a photo of the cover window 100 in a normal state (e.g., minimal or no cracks) when the pen is dropped from a height on the cover window 100 including the second film 130 according to an embodiment.

Referring to FIG. 7, in the present experiment, a comparative example is a cover window 100 including a second film 130 with only a base substrate 131 of which a modulus is 703 MPa, Embodiment A is a cover window 100 including a base substrate 131 with a modulus of 703 MPa and a pattern layer 132 with a modulus of 17 MPa, Embodiment B is a cover window 100 including a base substrate 131 with a modulus of 703 MPa and a pattern layer 132 with a modulus of 31 MPa, Embodiment C is a cover window 100 including a base substrate 131 with a modulus of 703 MPa and a pattern layer 132 with a modulus of 73 MPa, Embodiment D is a cover window 100 including a base substrate 131 with a modulus of 703 MPa and a pattern layer 132 with a modulus of 193 MPa, and Embodiment E is a cover window 100 including a base substrate 131 with a modulus of 703 MPa and a pattern layer 132 with a modulus of 248 MPa.

The table of FIG. 7 shows impact absorption rates (in percent, %) of the cover window 100 for each impact force N received by dropping an external object onto the top surface of the cover window 100. It can he observed that the impact absorption rate of the cover window 100 according to Embodiment A is the lowest when the modulus of the base substrate 131 included in the cover window 100 is 703 MPa. This supports the effect of the embodiment in which the condition of the modulus of the base substrate 131 and the pattern layer 132 for the aforementioned impact characteristic improvement, that is, when the modulus of the base substrate 131 is about 500 MPa to about 1.5 GPa, and the modulus of the pattern layer 132 is about 5 MPa to about 20 MPa.

Referring to FIG. 8, in pen drop experiments, Comparative Example 1 is a cover window 100 that includes a second film 130 only including a base substrate 131 of which a modulus is 703 MPa, Comparative Example 2 is a cover window 100 that includes a second film 130 including a base substrate 131 of which a modulus is 703 MPa and a layer of which a modulus is 17 MPa like a pattern layer 132 and has a flat surface rather than having protrusions 32, and Comparative Example 3 is a cover window 100 that includes a second film 130 including a base substrate 131 of which a modulus is 31 MPa and a layer of which a modulus is 31 MPa like a pattern layer 132 and has a flat surface rather than having protrusions 32. Embodiment F is a cover window 100 that includes a second film 130 including a base substrate 131 with a modulus of 703 MPa and a pattern layer 132 with a modulus of 17 MPa, while a protrusion 32 has a prism shape, and Embodiment G is a cover window 100 that includes a second film 130 including a base substrate 131 with a modulus of 703 MPa and a pattern layer 132 with a modulus of 17 MPa, while the shape of protrusion 32 is a microlens type.

The graph of FIG. 8 shows the range of pen drop heights at which the cover window 100 can withstand the impact without damage when the pen is dropped on the cover window 100 according to each of the comparative examples and embodiments.

In the graph of FIG. 8, compared to the case where there is no pattern layer 132 as in the embodiment or when the pattern layer 132 does not include protrusions 32 and is flat (Comparative Example 1, Comparative Example 2, and Comparative Example 3), it can be determined that the cover window 100 including the pattern layer 132 as in Embodiment F or Embodiment G can highly withstand the impact from the object falling from a higher height.

FIG. 9 is a photograph representing cracks in the cover window 100 according to Comparative Example 1, Comparative Example 2 or Comparative Example 3 of FIG. 8 when the pen drop height is, for example, approximately 9 centimeters, and FIG. 10 is a photograph representing a normal state of the cover window 100 without cracks occurring in the cover window 100 according to Embodiment F or Embodiment G. Through this, it can be determined that the impact dispersion and absorption power of the cover window 100 including the second film 130 according to one or more of the embodiments are improved, thereby improving the impact characteristic.

As such, according to one or more embodiment, the impact characteristic of a cover window 100 can be improved while maintaining a minimal thickness of the second film 130 without having to increase a thickness of the second film 130 to improve the impact characteristic of the cover window 100, and accordingly, the flexibility of the cover window 100 can be improved.

An embodiment of a method of manufacturing (or providing) the second film 130 will be described with reference to FIG. 5 and FIG. 6.

Referring to the above-described FIG. 5 and FIG. 6, after coating (or providing) a polymer resin for the pattern layer 132 on the base substrate 131, the coated layer is patterned into a plurality of the protrusion 32 to form the pattern layer 132. In this case, as the coating method, various methods such as bar coating and slot die coating may he used. As the patterning method, methods such as injection, extrusion, numerical control (NC) processing, and roll stamping may be used. The plurality of protrusions 32 within the pattern layer 132 may define a space between protrusions 32 which are adjacent to each other along the base substrate 131.

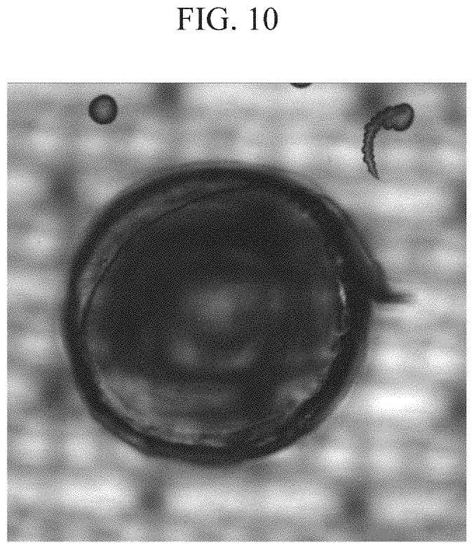

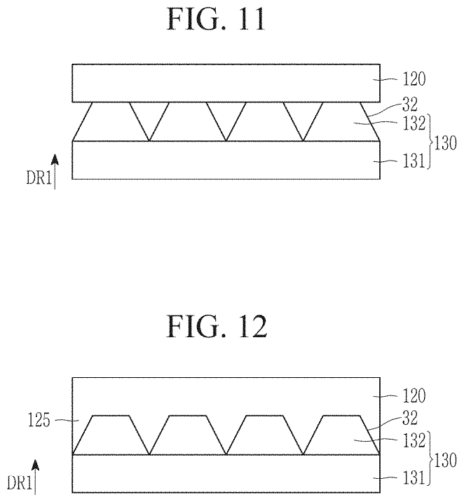

Referring to FIG. 11 to FIG. 16, embodiments of a cover window 100 and a method of providing the cover window 100 will be described, together with the above described drawings.

FIG. 11 and FIG. 12 are cross-sectional views of an embodiment of a second film 130 and an adhesive layer which is on the second film 130.

As previously described, after providing a second film 130, a first adhesive layer 120 in the form of a film is disposed on a pattern layer 132 of the second film 130, and pressure is applied to the stacked structure including the first adhesive layer 120 and the second film 130. Under force of the pressure, a protrusion 32 of the pattern layer 132 may maintain the shape as shown in FIG. 5, but as shown in FIG. 11, a high point HP of the protrusion 32 of the pattern layer 132 is flattened, and thus it may become an approximately trapezoid-shaped protrusion 32 when viewed from a cross-section. Accordingly, when the impact is transmitted from the top of a display device, most of the impact can be distributed upwards through the flattened top surface of the protrusion 32 of the cover window 100 within the display device. A space may be defined by the protrusions 32 which are adjacent to each other, together with the first adhesive layer 120 (or with the first adhesive layer 120 and the base substrate 131).

Referring to FIG. 12, due to the characteristic of the first adhesive layer 120 having a low modulus, a portion of the lower portion of the first adhesive layer 120 may extend into a space between the adjacent protrusions 32 of the pattern layer 132. That is, the pattern layer 132 may further include the plurality of protrusions 32 defining a space between protrusions 32 which are adjacent to each other along the base substrate 131. The adhesive layer may include both a portion outside of the pattern layer 132, and the portion outside of the pattern layer 132 extending into the space between protrusions 32 which are adjacent to each other to define a filling layer 125. Accordingly, a filling layer 125 as portions of the first adhesive layer 120 may be formed in the space between the adjacent protrusions 32. The filling layer 125 may include the same material as the first adhesive layer 120. Due to the filling layer 125, the impact characteristic of the second film 130 can be further improved.

Referring to FIG. 4, a first film 110 may be placed (or provided) on the first adhesive layer 120 and attached thereto.

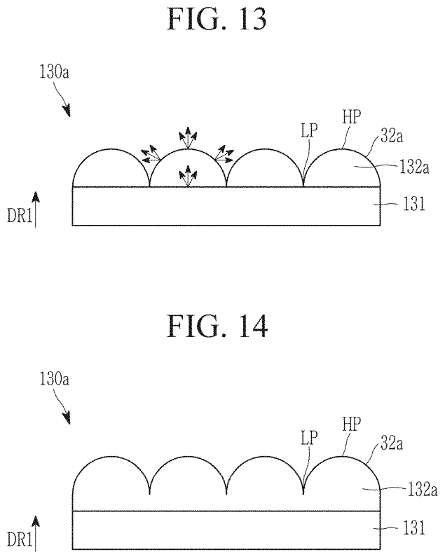

FIG. 13 and FIG. 14 are cross-sectional views of embodiments of second films.

Referring to FIG. 13 and FIG. 14, a second film 130a may include a pattern layer 132a having a different shape from the pattern layer 132. That is, the second film 130a may include a pattern layer 132a including a protrusion 32a in the form of a microlens.

Each protrusion 32a may contain a high point HP farthest from a base substrate 131 and a low point LP closest to the base substrate 131. Since the protrusion 32a is in the form of a microlens, the high point HP may be rounded rather than sharp.

As shown in FIG. 13, the low point LP may touch or coincide with the top surface of the base substrate 131, and as shown in FIG. 14, the low point LP may be spaced apart from the top surface of the base substrate 131. In the case of the embodiment shown in FIG. 13, the pattern layer 132a may have a substantially zero thickness in the low point LP, and in the case of the embodiment shown in FIG. 14, the pattern layer 132a may have a thickness that is substantially greater than zero at the low point LP.

Referring to FIG. 13, when the impact is transmitted from the top of the cover window 100 and/or the display device including the same, most of the impact is distributed in the upper, upper left, or upper right direction (in a cross-section view) as indicated by the multiple arrows in the plane of the protrusion 32a of the pattern layer 132a protruded upwardly. Impact absorbed by the protrusion 32a can also be reflected at the interface between the protrusion 32a and the base substrate 131. Therefore, transmission of the image to the second film 130a and the display panel 200 therebelow may he reduced or effectively prevented.

In addition, the impact transmitted from the top of the cover window 100 and/or the display device including the same is delayed within the second film 130a formed of the base substrate 131 and the pattern layer 132a having different materials from each other, such that that transmission of the impact to other places within the cover window 100 and/or the display device including the same can be mitigated.

Within the display device which is folded, the pitch PT and height HT of the protrusion 32a of the pattern layer 132a can he appropriately set to reduce or effectively prevent damage to the second film 130a by the stress and not to deteriorate the flexibility of the cover window 100 and/or the display device including the same. In an embodiment, for example, in the display device which is folded and has the curvature radius of about 1 millimeter, the pitch PT of the plurality of protrusions 32a may be about 20 micrometers to about 50 micrometers, and the height HT of the protrusions 32a may be about 10 micrometers to about 25 micrometers.

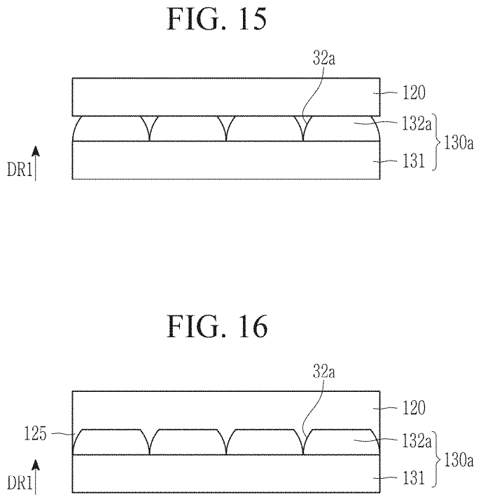

FIG. 15 and FIG. 16 are cross-sectional views of embodiments of a second film 130a and an adhesive layer which is on the second film 130a.

After the providing of a second film 130a through one or more embodiment of a method of providing the second film 130 described above, a first adhesive layer 120 in the form of a film is disposed on a pattern layer 132a of the second film 130a. As shown in FIG. 15, the microlens shape of the protrusion 32a may be flattened to move the high point HP of the protrusion 32a of the pattern layer 132a closer to the base substrate 131 from an original height (in FIGS. 13 and 14, for example). That is, the protrusion 32a may have a flat top surface (in FIGS. 15 and 16, similar to FIG. 12, or example) to define a flattened microlens shape. According to this, when the impact is transmitted from the top of the cover window 100 and/or the display device including the same, most of the impact can be distributed upward through the flattened top surfaces of the protrusions 32a.

Further, referring to FIG. 16, due the characteristic of the first adhesive layer 120 having a low modulus, a portion of the first adhesive layer 120 may extend into a space between the adjacent protrusions 32a of the pattern layer 132a from outside of the pattern layer 132a. Accordingly, a filling layer 125 may be formed in the space between the adjacent protrusions 32a. The filling layer 125 may include the same material as the first adhesive layer 120.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A cover window of a display device comprising:
a first film,
a second film facing the first film and closer to a display panel of the display device than the first film, and
an adhesive layer between the first film and the second film and adhering the first film to the second film,
wherein the second film comprises in order in a direction towards the first film:
a base substrate haying a modulus, and
a pattern layer facing the base substrate and having a modulus, the pattern layer including:
a plurality of protrusions arranged along the base substrate,
each protrusion among the plurality of protrusions haying a width, and
the widths of the protrusions decreasing in the direction towards the first film,
wherein within the pattern layer:
the modulus of the base substrate is about 500 megapascals to about 1.5 gigapascals when the modulus of the pattern layer is about 5 tnegapascals to about 20 megapascals, or
the modulus of the base substrate is about 3.5 gigapascals or more when the modulus of the pattern layer is about 30 megapascals to about 50 megapascals.

2. The cover window of claim 1, wherein the first film comprises a protection film which defines a top surface of the cover window which is farthest from the display panel.

3. The cover window of claim 1, wherein within the second film, the pattern layer comprises a polymer resin including acryl, urethane or silicone.

4. The cover window of claim 3, wherein within the second film, the base substrate comprises a polymer material including amide, ester ether or carbon.

5. The cover window of claim 3, wherein within the second film, the base substrate comprises a polymer material including terephthalate, imide, or aramid.

6. The cover window of claim 1, wherein within the second film:
the base substrate includes a top surface closest to the first film,
the protrusion comprises a high point farthest from the base substrate and a low point closest to the base substrate, and
the low point contacts the top surface of the base substrate.

7. The cover window of claim 1, wherein within the second film:
the base substrate includes a top surface closest to the first film,
the protrusion comprises a high point farthest from the base substrate and a low point closest to the base substrate, and
the low point is spaced apart from the top surface of the base substrate.

8. The cover window of claim 1, wherein within the pattern layer, the protrusion comprises:
a flat top surface which is closest to the adhesive layer and defines a high point of the protrusion which is farthest from the base substrate, and
a low point closest to the base substrate.

9. The cover window of claim 8,
the pattern layer further includes the plurality of protrusions defining a space between protrusions adjacent to each other along the base substrate, and
the adhesive layer includes:
a portion outside of the pattern layer, and
the portion outside of the pattern layer extending into the space between protrusions adjacent to each other to define a filling layer.

10. The cover window of claim 1, wherein within the pattern layer, the protrusion has a shape of a prism or a microlens.

11. A display device comprising:
a display panel, and
a cover window facing the display panel, the cover window comprising a first film, an adhesive layer, and a second film in order in a direction toward the display panel,
wherein within the cover window, the second film comprises in order in a direction away from the display panel:
a base substrate, and
a pattern layer facing the base substrate, the pattern layer including:
a plurality of protrusions arranged along the base substrate,
each protrusion among the plurality of protrusions having a width, and
the widths of the protrusions decreasing in the direction away from the display panel.

12. The display device of claim 11, wherein within the cover window, the first film comprises a protection film which defines a top surface of the cover window which is farthest from the display panel.

13. The display device of claim 11, wherein within the second film of the cover window:
the base substrate includes a top surface closest to the first film,
the protrusion comprises a high point farthest from the base substrate and a low point closest to the base substrate, and
the low point contacts the top surface of the base substrate.

14. The display device of claim 11, wherein within the second film of the cover window:
the base substrate includes a top surface closest to the first film,
the protrusion comprises a high point farthest from the base substrate and a low point closest to the base substrate, and,
the low point is spaced apart from the top surface of the base substrate.

15. The display device of claim 11, wherein within the second film of the cover window, the protrusion comprises:
a flat top surface which is closest to the adhesive layer and defines a high point of the protrusion which is farthest from the base substrate, and
a low point closest to the base substrate.

16. The display device of claim 15, wherein within the cover window:
the pattern layer further includes the plurality of protrusions defining a space between protrusions adjacent to each other along the base substrate, and
the adhesive layer includes:
a portion outside of the pattern layer, and
the portion outside of the pattern layer extending into the space between protrusions adjacent to each other to define a filling layer.

17. The display device of claim 11, wherein within the cover window:
each of the base substrate and the pattern layer has a modulus, and
the modulus of the base substrate is about 500 megapascals to about 1.5 gigapascals when the modulus of the pattern layer is about 5 megapascals to about 20 megapascals.

18. The display device of claim 17, wherein within the cover window:
the base substrate comprises a polymer material including amide, ester ether or carbon, and
the pattern layer comprises a polymer resin including acryl, urethane or silicone.

19. The display device of claim 17, wherein
the base substrate comprises a polymer material including terephthalate, imide, or aramid, and
the pattern layer comprises a polymer resin including acryl, urethane or silicone.

20. A method of providing a cover window of a display device, comprising:
providing a coating layer by providing a polymer resin to a base substrate of the cover window, the base substrate having a modulus;
providing a pattern layer of the cover window including a plurality of protrusions arranged along the base substrate, by patterning the coating layer, the pattern layer including:
each protrusion among the plurality of protrusions having a modulus and a width, and
the widths of the protrusions decreasing in a direction away from the base substrate;
providing an adhesive layer facing the base substrate with the plurality of protrusions of the pattern layer therebetween; and
providing a protection film of the cover window which faces the plurality of protrusions of the pattern layer with the adhesive layer therebetween,
wherein within the cover window:
the modulus of the base substrate is about 500 megapascals to about 1.5 gigapascals when the modulus of the pattern layer is about 5 megapascals to about 20 megapascals, or
the modulus of the base substrate is about 3.5 gigapascals or more when modulus of the pattern layer is about 30 megapascals to about 50 megapascals.
